(19) United States
(12) Patent Application Publication
(10) Pub. No.: US 2012/0241876 A1
(43) Pub. Date: Sep. 27, 2012

(54) SYSTEM AND METHOD FOR IMPROVING FREQUENCY RESPONSE

(76) Inventor: Charles A. Still, Clinton, MI (US)

(21) Appl. No.: 13/072,222

(22) Filed: Mar. 25, 2011

(51) Int. Cl. H01L 29/84; H01L 21/66; H01L 23/488

(52) U.S. Cl. 257/415; 257/738; 438/15; 257/E29.324; 257/E23.023; 257/E21.529

(57) ABSTRACT

An electrical system and method for making the same includes a main circuit board and a plurality of contact pads located on a surface of the main circuit board. The contact pads are electrically conductive. Additionally, an integrated circuit package having at least one electrical device is attached to the surface of the main circuit board. A ball grid array made from a plurality of solder balls is located on a bottom side of the integrated circuit package. The ball grid array has a plurality of solder balls being electrically conductive and in electrical communication with the at least one electrical device. The solder balls further include solder balls of different material properties.

### BACKGROUND

1. Field of the Invention

The present invention generally relates to systems and methods for improving the frequency response of electrical systems, such as microelectromechanical systems (“MEMS”).

2. Brief Description of the Known Art

Sensors, such as gyroscopic sensors, employ various MEMS devices to sense angular rotation. These MEMS devices often rely on capacitively driven or piezoelectronically driven oscillating paired sense elements.

One effect of the oscillating paired sense elements is that the mass, suspension, or driving frequency of the individual elements of an integrated circuit package containing the MEMS device may not be exactly matched. This mismatch results in a net oscillation exciting the integrated circuit package containing the MEMS device. The result in excitation frequency may coincide with a modal frequency of the circuit board to which the integrated circuit package containing the MEMS device is attached to. When the excitation and resonant frequencies overlap, the reference frame of the MEMS device is no longer fixed. The constructive or destructive interference of the overlap in frequencies results in a shift of the output signal of the MEMS device.

The range of frequencies for an integrated circuit package having a MEMS device may vary by as much as 15-20%. This variance reflects manufacturing tolerance variations although the entire assembly from the MEMS device to the integrated circuit package, and finally to the circuit board to which the integrated circuit package containing the MEMS device is attached to. Manufacturers of these systems typically employ statistical distribution of the observed tolerance variations of the various components comprising the system. Outliers are rejected. Because the outliers may also depend on manufacturing process not directly under the control of the manufacturer assembling the integrated circuit package, further outliers are rejected, driving up the manufacturing costs of these systems.

Referring to FIG. 1, a typical overlap of the frequency of the integrated circuit package and the MEMS device are shown. The MEMS resonant frequency 10 overlaps portions of the modal frequency 12 of the package. This overlap results in a shift of the output signal from the MEMS device, making the output of the MEMS device less accurate and less useful.

One such solution to this problem is to recalibrate the reported angular rate in the internal software of the MEMS device. While this addresses the offset of the board level assembly at the time of calibration, it accommodates but does not resolve the underlying root cause of the problem—MEMS excitation resonant frequency overlap. Subsequent changes in the boundary conditions of the integrated circuit package as may occur due to the strain relief of solder joints or the stress induced from circuit board flexing, may result in a shift of the response and invalidate the software recalibration over time.

### BRIEF SUMMARY

An electrical system and method for making the same includes a main circuit board and a plurality of contact pads located on a surface of the main circuit board. The contact pads are electrically conductive. Additionally, an integrated circuit package having at least one electrical device is attached to the surface of the main circuit board. A ball grid array made from a plurality of solder balls is located on a bottom side of the integrated circuit package. The ball grid array has a plurality of solder balls being electrically conductive and in electrical communication with the at least one electrical device. The ball grid array also mechanically couples the integrated circuit package to the main circuit board. The solder balls further include solder balls of different material properties.

Further objects, features and advantages of this invention will become readily apparent to persons skilled in the art after a review of the following description, with reference to the drawings and claims that are appended to and form a part of this specification.

### BRIEF DESCRIPTION OF THE DRAWINGS

FIG. 1 illustrates the resonant and modal frequencies of the MEMS device and the integrated circuit package, respectively;

FIG. 2 an electrical system having a main circuit board in electrical communication with an integrated circuit package having a ball grid array being comprised of solder balls of different material properties;

FIG. 3 is a more detailed illustration of the integrated circuit package of FIG. 2;

FIG. 4 illustrates a bottom side of the integrated circuit package shown in FIGS. 2 and 3;

FIG. 5 illustrates a more detailed view of a polymer core solder ball;

FIGS. 6 and 7 illustrate methods of manufacturing the electrical system shown in FIG. 1; and

FIGS. 8 and 9 illustrate the resonant and modal frequencies of the MEMS device and the integrated circuit package, respectively resonant when utilizing solder balls of different material properties.

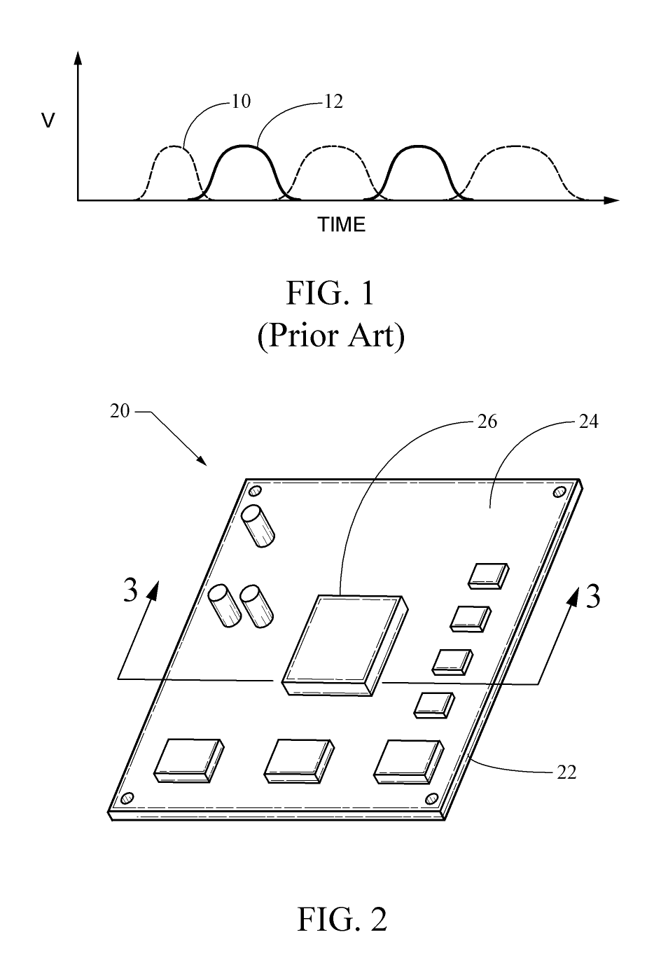

### DETAILED DESCRIPTION OF THE DRAWINGS AND THE PRESENTLY PREFERRED EMBODIMENTS

Referring to FIG. 2, an electrical system 20 is shown. The electrical system 20 includes a circuit board 22, which has a surface 24. Located on the surface 24 is an integrated circuit package 26.

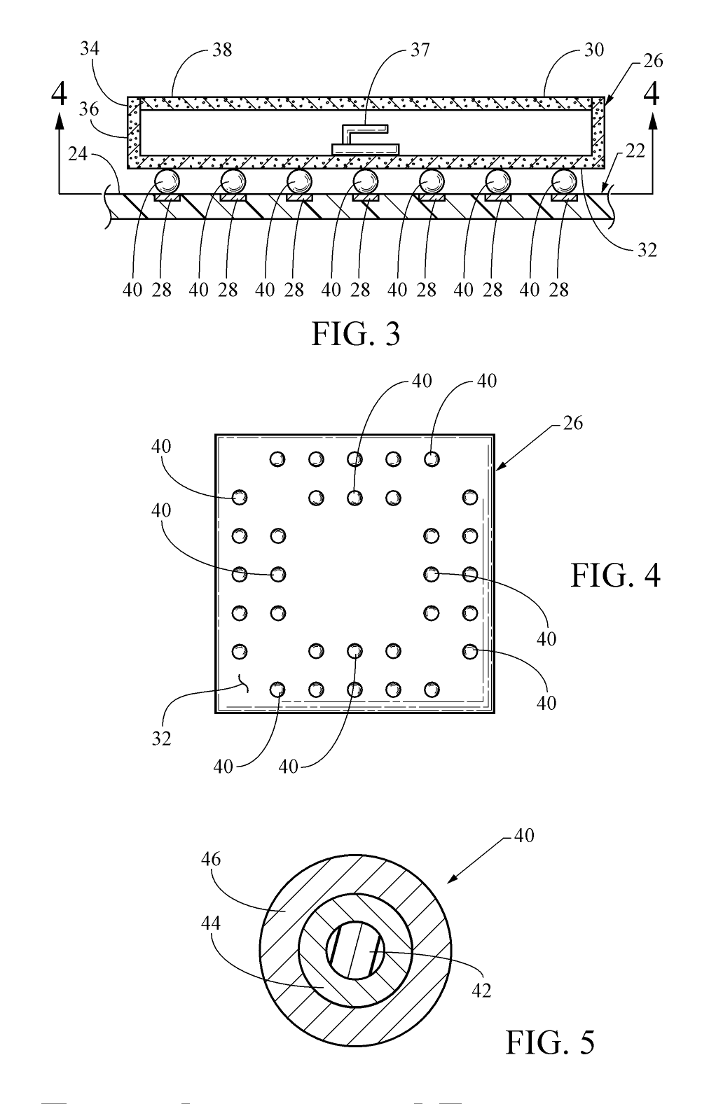

Referring to FIG. 3, a more detailed view of the integrated circuit package 26 and the circuit board 22 are shown, generally taken along lines 3-3 of FIG. 2. The circuit board 22 includes a plurality of contact pads 28. The plurality of contact pads 28 are electrically conductive and are in electrical communication with other components that are in electrical communication with the circuit board 22.

The integrated circuit package 26 has a top side 30 and a bottom side 32. The integrated circuit package 26 includes a housing 34 that is ceramic and generally encapsulates an electrical device 37. The ceramic housing 34 generally includes a main body 36 and a lid 38. When the lid 38 is attached to the main body 36, the ceramic housing 34 encapsulates the electrical device 36. The electrical device 36 is generally a MEMS device, which may be a gyroscopic sensor.

Located on the bottom surface 32 of the electrical package 26 are a plurality of solder balls 40 which form a ball grid array. The solder balls 40 are electrically conductive and are in electrical communication with the electrical device 36. In turn, the solder balls 40 are directly adjacent to a corresponding contact pads 28 so that an electrical connection is formed between the contact pads 28 and the solder balls 40. This, in turn, creates an electrical communication path between the electrical device 36 and the contact pads 28 of the circuit board 22. This then communication path allows the electrical device 36 to communicate with other electrical systems.

Referring to FIG. 4, the bottom side 26 of the electrical package 24 is shown in more detail. As stated previously, a ball grid array made up of solder balls 40 of solder at the bottom surface 26 of the electrical package 24 has a plurality of solder balls 40 are attached thereto. The solder balls 40 making up the ball grid array are made of different material properties. Generally, some of the solder balls 40 forming the ball grid array will be made of a high melting point solder, while other solder balls 40 will be polymer core solder balls. It should be understood that it is possible that only one solder ball 40 can be made of the high melting point solder and the rest being polymer core solder balls. Conversely, it is also possible that only one solder ball 40 is a polymer core solder ball, while the other solder balls 40 are made from a high melting point solder. Generally, the high melting point solder forming a solder ball is approximately 90 percent tin and 10 percent lead.

It is important to note that the elasticity of a solder ball 40 made of high melting point solder differs from that of a solder ball that is a polymer core solder ball. Generally, the high melting point solder balls are less elastic (i.e. lower modulus of elasticity) than the polymer core solder balls and by utilizing these two different types of solder balls, overlap between the resonant frequencies of the ceramic package 26 and the circuit board 22 can be made such that there is minimal overlap, reducing errors

Referring to FIG. 5, a more detailed illustration of a solder ball 40 that is a polymer core solder ball is shown. Here, the polymer core solder ball 40 has a nonconductive polymer core 42. The nonconductive polymer core 42 is encapsulated by an immediately adjacent conductive intermediate layer 44. This conductive intermediate layer 44 is an encapsulated with an adjacent conductive outer layer 46. The conductive intermediate layer 44 is generally made from copper, while in the conductive outer layer 46 is generally made from solder.

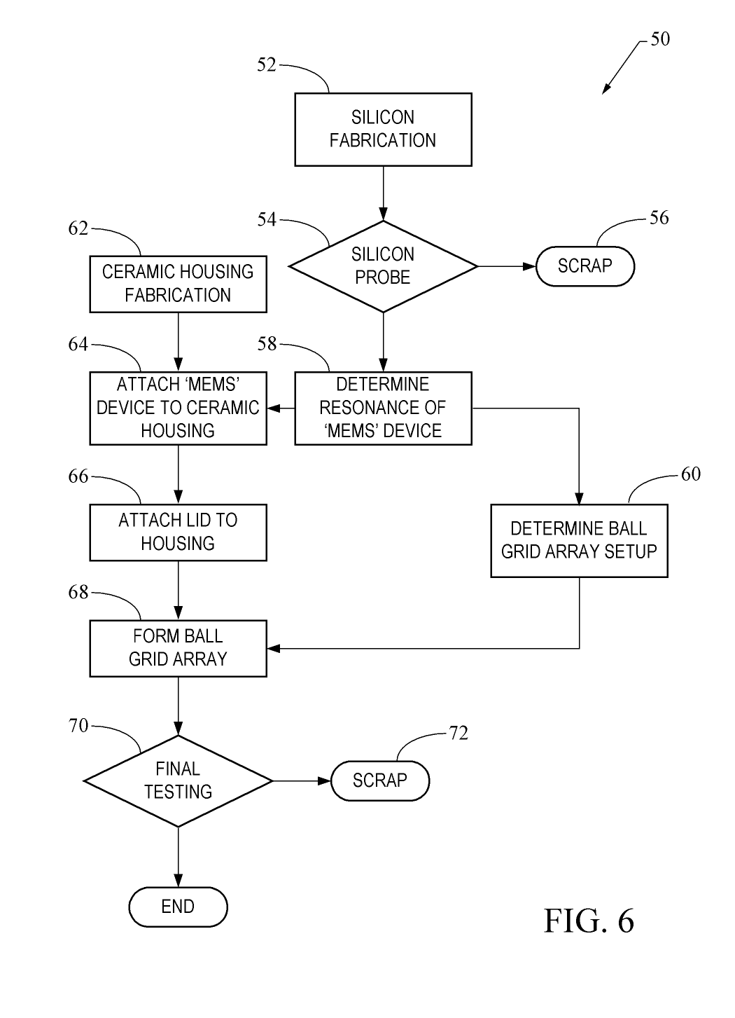

Referring to FIG. 6, a method 50 for manufacturing the system 20 is shown. Reference will be made to FIGS. 2 and 3 when discussing the method 50 of FIG. 6. The method 50 begins with the step 52 of fabricating the device 36. The fabrication step 52 generally involves creating the electrical device 36 through a silicon fabrication process. Next, in step 54, the electrical device 36 is tested by the use of a silicon probe to determine if the electrical device 36 is operating properly. If the electrical device 36 is not operating properly, the electrical device 36 is scrapped, as illustrated in step 56. If the electrical device 36 is operating correctly, a determination will be made in step 58 of the resonant frequency of the electrical device, which has previously mentioned as generally a MEMS device. The variation in the driving frequency of the MEMS device is a resultant of all of the individual tolerances of the constituent components within the driver circuit. The resultant frequency may be determined by oscilloscopes or other monitoring equipment, or, by diagnostic outputs from the driving circuit.

In step 60, once the resonant frequency of the MEMS device is determined, a determination will be made as to the ball grid array set up. More specifically, a determination will be made how many and which solder balls 40 of the ball grid array will be made of a high melting point solder and which solder balls will be polymer core solder balls. As previously stated, by varying the types of solder balls forming the ball grid array, the resonant frequencies of the circuit board 22 and the ceramic package 26 can be made such that there will be very little frequency overlap.

In step 62 the housing 34 for the integrated circuit package 26 is fabricated. In step 64, the electrical device 36 is attached to the ceramic housing 34. After that, in step 66 the lid 38 is attached to the main body 36 of the ceramic housing 34.

In step 68, the ball grid array is formed based on the determination of the ball grid array done in step 60. As previously stated, the ball grid array will be made of solder balls 40 of different material properties. Generally, some of the solder balls will be made of high melting point solder, while other solder ball will be polymer core solder balls. In step 70, a final test of the electrical package 26 is performed to make sure that the electrical package 26 is operating properly. If the electrical package 26 is operating properly the method 50 ends. If not, the electrical package 26 is scrapped, as shown in step 72. The type of solder balls used is determined by a lookup table that correlates integrated circuit package 26 frequency response data to a particular configuration of various types of solder balls 40. This lookup table is generated by means of experimental testing of assembled integrated circuit packages 26.

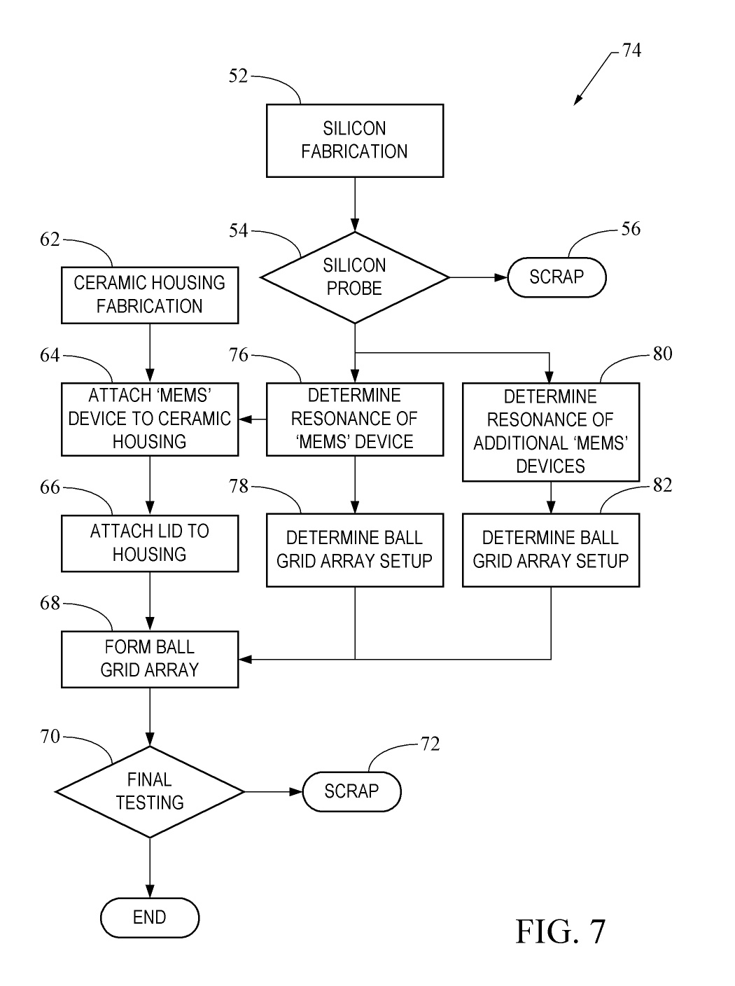

Referring to FIG. 7 another method 74 for attaching the solder balls 40 to the package 26 is shown. In the method 74 some steps are similar to steps previously described in FIG. 6. Similar steps use the same reference numerals and a description of these steps will not be given as the previous description given in the paragraphs above still applies.

In method 50 of FIG. 6, a determination is made regarding the resonant frequency of the electrical device 36. The method 50 characterizes the electrical device 36 and assumes that all other electrical devices that are similar are assumed to have similar resonant frequencies. The method 74 of FIG. 7 differs in that the resonant frequency of the electrical device 36 is assumed to be different even if the same electrical device 36 is being used. In other words, when manufacturing packages 26 that contain electrical devices 36, a determination will be made as to each electrical device 36. From there, each package 36 will get a customized ball grid array having solder balls 40 of different material properties to match that electrical device 36 exact resonant frequency.

As stated before, many of the steps of method 74 are similar to the steps in method 50. Referring to step 76, a determination of the resonant frequency of the electrical device 36 is made. From that determination, a ball grid array set up will be determined as shown in step 78. Thereafter, step 68 is performed in which the ball grid array comprising solder balls of different material properties is made based on the determination made in step 78.

As stated before, the method 74 considers that electrical devices 36, even having the same part number, may have slight variations in their resonant frequencies. As such, this method 74 considers determining the frequencies of additional electrical devices 36, as shown in step 80. Thereafter, a ball grid array comprising of the solder balls 40 having different material properties will be determined. Like before, in step 68 a ball grid array is formed based on the determination made in step 82. Thereafter, similar steps regarding final testing are performed as described previously in FIG. 6.

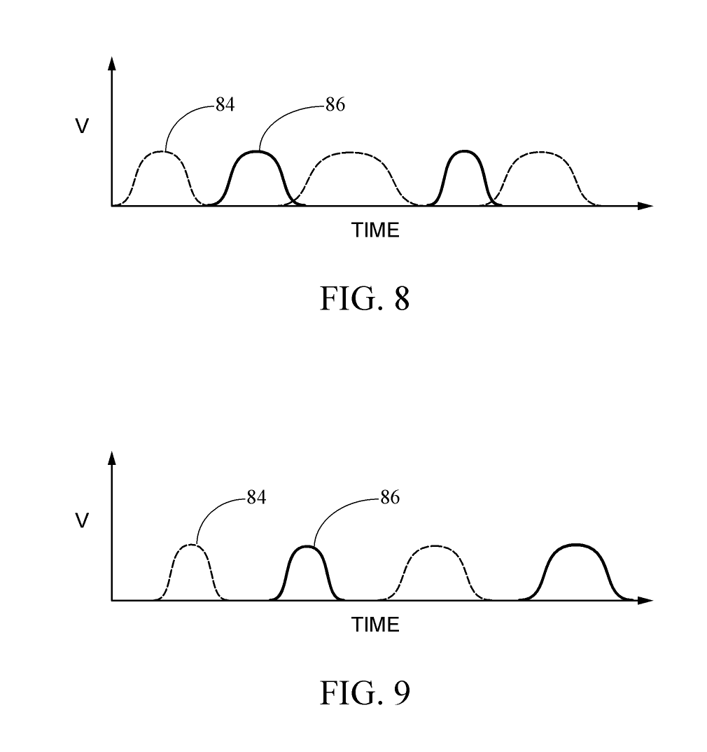

Referring to FIG. 8, the modal frequency 84 of the package 26 and the resonant frequency 86 of the circuit board 22 are shown. The method disclosed in FIG. 6 has minimized if not completely eliminated the overlap between frequency 84 and 86.

Referring to FIG. 9, the modal frequency of the package 84 and resonant frequency of the circuit board 86 show no overlap. Systems made using the method disclosed in FIG. 7, wherein a customized ball grid array is made for each and every electrical device manufactured, have no overlap.

By utilizing a ball grid array made of solder balls having different material properties, it is now possible to minimize if not completely eliminate overlap of the resonant frequencies of the circuit board and the ceramic package containing the electrical device. By so doing, a significant reduction in the scrap rate during the manufacturing of such systems can be eliminated, significantly reducing the costs of manufacturing.

As a person skilled in the art will readily appreciate, the above description is meant as an illustration of the principles of this invention. This description is not intended to limit the scope or application of this invention in that the invention is susceptible to modification, variation and change, without departing from spirit of this invention, as defined in the following claims.

1. A electrical system comprising:
a main circuit board, the main circuit board having a surface;
a plurality of contact pads located on the surface of the main circuit board, the contact pads being electrically conductive;
an integrated circuit package having at least one electrical device;
a ball grid array located on a bottom side of the integrated circuit package, the ball grid array comprising a plurality of solder balls, the plurality of solder balls being electrically conductive and in electrical communication with the at least one electrical device;
wherein each of the plurality of solder balls are directly adjacent to one of the plurality of contact pads, whereby an electrical connection is formed between the plurality of contact pads that are directly adjacent to the solder balls and the electrical device; and
wherein the solder balls further comprise solder balls of different material properties.

2. The system of claim 1, wherein the solder balls further comprise at least one high melting point solder ball and at least one polymer core solder ball.

3. The electrical system of claim 2, wherein the at least one high melting point solder ball is made of about 90% tin and about 10% lead.

4. The system of claim 2, wherein the at least one polymer core solder ball further comprises:
a non conductive polymer core;
a conductive intermediate layer adjacent to the polymer core; and
a conductive outer layer adjacent to the conductive intermediate layer.

5. The system of claim 4, wherein the conductive intermediate layer is made from copper.

6. The system of claim 4, wherein the conductive outer layer is made from solder.

7. The system of claim 2, wherein the at least one electrical device is a microelectromechanical system.

8. The system of claim 7, wherein the microelectromechanical system is a gyroscopic sensor.

9. The system of claim 7, wherein the number of polymer core solder balls forming the ball grid array is based on the frequency response of the electrical device.

10. The system of claim 1, wherein the integrated circuit package further comprises a ceramic housing encapsulating the at least one electrical device.

11. A method for producing an electrical system, the method comprising the steps of:
measuring a frequency response of an electrical device, the electrical device being encapsulated by an integrated circuit package, the integrated circuit package having a plurality of contact pads located on a bottom surface of the integrated circuit package, the contact pads being in electrical communication with the electrical device;
attaching a plurality of solder balls directly to one of the plurality of contact pads to form a ball grid array, whereby an electrical connection is formed between the plurality of contact pads that are directly adjacent to the solder balls and the electrical device, wherein the solder balls further comprise at least one high melting point solder ball and at least one polymer core solder ball; and
wherein the number of polymer core solder balls forming the ball grid array is based on the frequency response of the electrical device.

12. The method of claim 10, wherein the at least one high melting point solder ball is made of about 90% tin and about 10% lead.

13. The method of claim 10, wherein the at least one polymer core solder ball further comprises:
a non conductive polymer core;
a conductive intermediate layer adjacent to the polymer core; and
a conductive outer layer adjacent to the conductive intermediate layer.

14. The method of claim 10, wherein the conductive intermediate layer is made from copper.

15. The method of claim 13, wherein the conductive outer layer is made from solder.

16. The method of claim 10, wherein the at least one electrical device is a microelectromechanical system.

17. The method of claim 10, wherein the microelectromechanical system is a gyroscopic sensor.

18. The system of claim 10, wherein the integrated circuit package further comprises a ceramic housing encapsulating the at least one electrical device.
